(19) United States
(12) Patent Application Publication
(10) Pub. No.: US 2020/0315045 A1
(43) Pub. Date: Oct. 1, 2020

(54) Fastening System and Associated Locking Process

(71) Applicant: Siemens Aktiengesellschaft, Muenchen (DE)

(72) Inventor: Leo Fruehstueck, Wien (AT)

(21) Appl. No.: 16/311,029

(22) PCT Filed: Jun. 19, 2017
(86) PCT No.: PCT/EP2017/064897

§ 371 Date: Dec. 18, 2018

(51) Int. Cl. H05K 5/02

(52) U.S. Cl. CPC H05K 5/0221; H05K 5/0204

(57) ABSTRACT

A fastening system includes a plurality of adapters, wherein a first adapter has at least a first slotted tab with a first slot and a second slotted tab with a second slot, wherein a second adapter has at least a first guide tab with a first guide bolt and a second guide tab with a second guide bolt, and a third adapter has at least a first securing bolt and a second securing bolt, where each guide bolt is arranged in the respectively assigned slot in an assembled state of the first and second adapter, and where the first and second securing bolts can be locked through the associated slotted tabs such that the required number of fastener can be reduced and the relevant apparatus remains in its position even when the fasteners are released.

### CROSS-REFERENCE TO RELATED APPLICATIONS

This is a U.S. national stage of application No. PCT/EP2017/064897 filed Jun. 19, 2017. Priority is claimed on EP Application No. filed Jun. 27, 2016, the content of which is incorporated herein by reference in its entirety.

### BACKGROUND OF THE INVENTION

### 1. Field of the Invention

The invention relates to a fastening system having a first adapter, a second adapter and a third adapter, in particular for and connectable to an electronic device.

### 2. Description of the Related Art

Electronic devices, such as the Siemens SINAMICS S120 low voltage converter, often have tabs with drilled holes on their housings which can be, for example, on the upper sides or the undersides of the housings and are mounted via these tabs in equipment cabinets. The equipment cabinets also have drilled holes. With these drilled holes and screw connections, an electronic device is mounted in an equipment cabinet and secured therein against unintended movements. If no further fasteners or holding devices are provided, the disadvantage arises therefrom that, for example, during an installation procedure, the electronic device must be supported by an installer until the screw connections have been tightened. In order to ensure accessibility with tools (e.g., screwdrivers), i.e., so as to be able to tighten and loosen screws, these tabs must be exposed, i.e., arranged protruding beyond the housing of the electronic device. As a result, there is an increased space requirement in the equipment cabinet. Further devices that are mounted in the equipment cabinet besides the electronic device cannot be arranged directly adjacent thereto, but spacings must be preserved.

DE 10 2014 005 708 A1 describes a modular fastening system for building facade panels in which at least one hook-shaped connecting element is arranged on a fastening fitting, into which connecting element a form-corresponding connecting receptacle is mounted on the rear side of a facade panel.

DE 71 29 501 U disclosesa holder for an electronic device, which comprises a base plate to which an insulating part is connected. Tabs arranged on the electronic device are introducible into cut-outs in the base plate or the insulating part. Hooks connected to the electronic device latch into retaining springs of the insulating part. Due to the tabs, the cut-outs and the retaining springs, the electronic device is locked in the holder.

### SUMMARY OF THE INVENTION

It is therefore an object of the invention to provide an improved fastening system as compared to the prior art.

This and other objects and advantages are achieved in accordance with the inventionby a fastening system, where the first adapter comprises at least one first slotted tab with a first slot and a second slotted tab with a second slot, which are arranged at an angle, where the second adapter comprises at least one first guide tab with a first guide pin and a second guide tab with a second guide pin, which are arranged angled, where the third adapter comprises at least one first securing pin and a second securing pin, where in an adjoined joined-together state of the first adapter with the second adapter in which the first adapter adjoins the second adapter, the second adapter is displaceably connected to the first adapter and the, in particular electronic, device connected to the second adapter is held by the at least first securing pin and the second securing pin, the first guide pin is arranged in the first slot and the second guide pin is arranged in the second slot, and where the at least first securing pin, arranged between the at least first slotted tab and the at least first guide tab in a first cut-out, is lockable via the at least first slotted tab and the at least first guide tab, and the second securing pin, arranged between the second slotted tab and the second guide tab in a second cut-out, is lockable via the second slotted tab and the second guide tab.

Consequently, the advantage is achieved that the, in particular electronic, device is brought into position and held via the first slotted tab, the second slotted tab, the first guide tab and second guide tab, the first securing pin and the second securing pin, i.e., is secured against unintended movements and the number of the required fastening means (e.g., screw connections) can be reduced. As a result, a reduction of the installation and removal effort is achieved.

If the, in particular electronic, device is held vertically in position by the first slotted tab, the second slotted tab, the first guide tab, the second guide tab, the first securing pin and the second securing pin, it remains also in its position with the fastener loosened and does not have to be supported by an installer or a device during the entire duration of an installation or removal procedure. Furthermore, no laterally protruding fastening tabs are required on a housing (e.g., on its upper side, underside, right or left side) of the, in particular electronic, device for fastening means (e.g., screw connections), so that a reduction of the space requirement for the, in particular electronic, device results, i.e., for example, more devices can be arranged per unit volume in an equipment cabinet.

An advantageous embodiment results when the first cut-out is arranged on the at least first guide tab and the second cut-out is arranged on the second guide tab, where the first cut-out has a width of greater than or equal to the diameter of the at least first securing pin and the second cut-out has a width of greater than or equal to the diameter of the second securing pin. As a result, a latching in of the first adapter and of the second adapter into the third adapter is enabled.

It is favorable if the at least first slotted tab, the second slotted tab, the at least first guide tab and the second guide tab are configured hook-shaped. As a result, a threading in of the first adapter and of the second adapter into the third adapter is facilitated.

An advantageous embodiment is obtained if the first adapter comprises at least one first securing tab and the second adapter comprises at least one third securing tab, where the at least first securing tab and the at least third securing tab comprise receptacles for a fastening means. As a result, locking of the fastening system and of the, in particular electronic, device connected thereto by fastening means (e.g., screws) is made possible.

It is favorable if the second adapter is releasably connected to the, in particular electronic, device. As a result, a rapid exchange (e.g., in the context of maintenance processes) of the fastening system and of the electronic device is enabled.

In an advantageous embodiment, conductors of the, in particular electronic, device are arranged in a region between the first adapter and the third adapter. With this, protection of the conductors against environmental influences, damage (e.g., through pinching, etc.) and a favorable utilization of an available installation space budget are achieved.

In a further advantageous embodiment the, in particular electronic, device has a first profile and a second profile, where the first profile is arranged in a first rail which is releasably connected to a first wall and the second profile is arranged in a second rail which is releasably connected to a third wall. With this measure, the introduction and removal of an, in particular electronic, device in an equipment cabinet and its positioning in the equipment cabinet is facilitated.

In an advantageous embodiment, a lever is connected to the first adapter, where the lever has a receptacle for a fastener. As a result, locking of the fastening system and of the, in particular electronic, device connected thereto via fasteners (e.g. screws) is made possible.

Furthermore, due to the functionality of folding in the lever, permanently protruding parts on the first adapter are prevented, so that for example transport damage (e.g., breaking off of the lever) etc. can be prevented.

In a further advantageous embodiment, the lever is configured in a signal color. With this, a clear indication of the state of the lever is obtained. In contrast to a folded-in state, in a folded-out state of the lever, the colored marking is visible and indicates this state to a user.

It is favorable if the first adapter is introduced in such a manner into the third adapter that at the end of this procedure the at least first slotted tab hangs on the at least first securing pin and the second slotted tab hangs on the second securing pin, if the second adapter, the first guide pin in the first slot and the second guide pin in the second slot move in such a manner that at the end of this movement process, the at least first securing pin is arranged at least between the at least first slotted tab and the at least first guide tab in the first cut-out and the second securing pin is arranged at least between the second slotted tab and the second guide tab in the second cut-out, andif the at least first securing tab is releasably connected with a fastener to the third securing tab.

With this measure, the procedure of positioning the, in particular electronic, device in an equipment cabinet is separated from the procedure of the locking. Consequently, the advantage is obtained that, for example, directly following the introduction of the electronic device into the equipment cabinet, this must no longer be firmly held in order to carry out the locking by the locking device(e.g., screws).

Following the releasing of the locking device, the, in particular electronic, device also remains in its position and is secured against unintentional movements.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention will now be described in greater detail making reference to exemplary embodiments, in which:

FIG. 1 shows an oblique view of an exemplary embodiment of a fastening system in accordance with the invention on an electronic device, where a first adapter and a second adapter are shown;

FIG. 2 shows an oblique view of a second exemplary embodiment of a fastening system in accordance with the invention on an electronic device, where a first adapter and a second adapter are shown;

FIG. 3 shows an oblique view of an exemplary embodiment of a third adapter of a fastening system in accordance with the invention and a part of a first wall;

FIG. 4 shows oblique views of a first exemplary embodiment of a fastening system in accordance with the invention, where three states of an exemplary locking process in accordance with the invention and, respectively, a first adapter, a second adapter and securing pins of a third adapter are shown in some portions;

FIG. 5 shows oblique views of a second exemplary embodiment of a fastening system in accordance with the invention, where two states of an exemplary locking process in accordance with the invention and, respectively, a first adapter, a second adapter and an electronic device are shown in some portions together with a lever;

FIG. 6 shows a side view of a second exemplary embodiment variant of a fastening system in accordance withthe invention, where a state of an exemplary locking process in accordance with the invention and a first adapter and a second adapter in some portions and securing pins of a third adapter are shown;

FIG. 7 shows an oblique view of a second exemplary embodiment variant of a fastening system in accordance with the invention, where a state of an exemplary locking process in accordance with the invention and an electronic device and a first wall are shown in some portions together with a lever;

FIG. 8 is a flowchart of the method in accordance with the invention; and

FIG. 9 is a flowchart of the method in accordance with an embodiment of the invention.

### DETAILED DESCRIPTION OF THE EXEMPLARY EMBODIMENTS

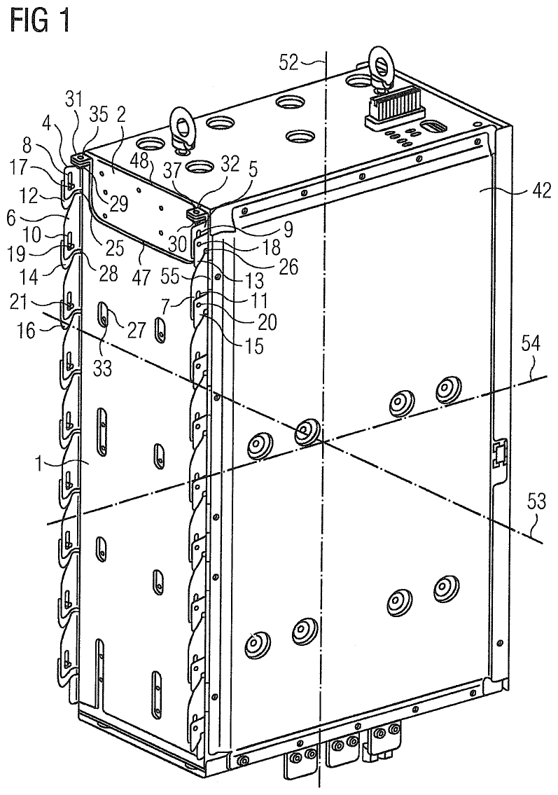

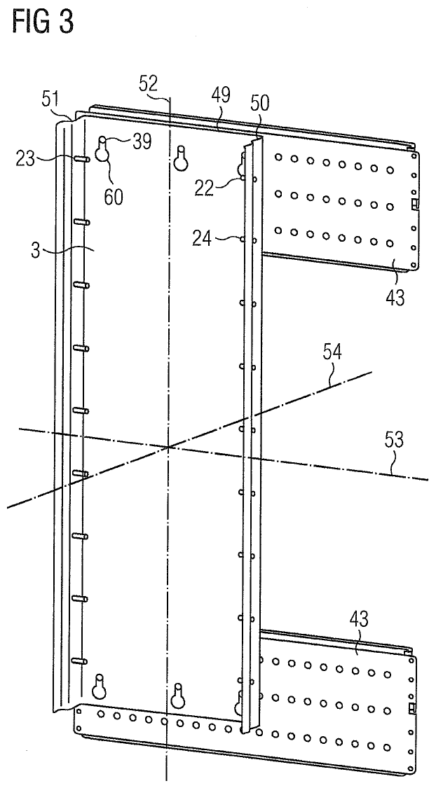

FIG. 1 shows a first exemplary embodiment of a fastening system in accordance with the invention with a first adapter 1 and a second adapter 2. A third adapter 3 shown in FIG. 3 is also part of the fastening system.

The first adapter 1 comprises a first slotted tab 4 with a first slot 8, a second slotted tab 5 with a second slot 9, a third slotted tab 6 with a third tab 10, a fourth slotted tab 7 with a fourth slot 11 and further slotted tabs with further slots. The first slotted tab 4, the second slotted tab 5, the third slotted tab 6, the fourth slotted tab 7 and the further slotted tabs have hook-shaped configurations and are arranged angled by 90° to a first base plate 47 of the first adapter 1.

In some portions of the first slotted tab 4, the second slotted tab 5, the third slotted tab 6, the fourth slotted tab 7 and the further slotted tabs, the first adapter 1 has U-shaped cross-sections.

The first slot 8, the second slot 9, the third slot 10, the fourth slot 11 and the further slots are arranged parallel to a vertical axis 52.

With the first base plate 47, the first adapter 1 is arranged parallel to a second base plate 48 of the second adapter 2 and is aligned adjoining it.

The second adapter 2 comprises a hook-shaped first guide tab 12 with a first guide pin 17, a hook-shaped second guide tab 13 with a second guide pin 18, a hook-shaped third guide tab 14 with a third guide pin 19, a hook-shaped fourth guide tab 15 with a fourth guide pin 20 and further hook-shaped guide tabs with further guide pins, which are arranged angled by 90° to the second base plate 48.

In some portions of the first guide tab 12, the second guide tab 13, the third guide tab 14, the fourth guide tab 15 and of the further guide tabs, the second adapter 2 has U-shaped cross-sections.

The first guide pin 17, the second guide pin 18, the third guide pin 19, the fourth guide pin 20 and the further guide pins are arranged parallel to a transverse axis 53.

In some portions of the first slotted tab 4, the second slotted tab 5, the third slotted tab 6, the fourth slotted tab 7 and of the further slotted tabs, the first guide tab 12, the second guide tab 13, the third guide tab 14, the fourth guide tab 15 and the further guide tabs adjoin the first adapter 1.

The first guide pin 17 is arranged in the first slot 8, the second guide pin 18 in the second slot 9, the third guide pin 19 in the third slot 10, the fourth guide pin 20 in the fourth slot 11 and the further guide pins are arranged in the further slots and can be moved therein in the direction of the vertical axis 52. As a result, the first adapter 1 can be displaced relative to the second adapter 2.

In FIG. 1, an assembly state is shown in which a first securing pin 22 (not shown) can be arranged between the first slotted tab 4, the first guide tab 12 and the third slotted tab 6 in a first cut-out 25 formed on the first guide tab 12, a second securing pin 23 (not shown) can be arranged between the second slotted tab 5, the second guide tab 13 and the fourth slotted tab 7 in a second cut-out 26 formed on the second guide tab 13, and further securing pins (not shown) can be arranged between further slotted tabs and further guide tabs in further cut-outs. An electronic device 42 connected to the second adapter 2 hangs in this assembly state on the first securing pin 22, the second securing pin 23 and the further securing pins.

The second adapter 2 comprises a first connecting tab 55 and further connecting tabs that are arranged angled by 90° to the second base plate 48 and angled by 180° to the first guide tab 12, the second guide tab 13, the third guide tab 14, the fourth guide tab 15 and the further guide tabs.

With the first connecting tab 55 and the further connecting tabs and screw connections (not shown), the second adapter 2 is connected to the electronic device 42.

Furthermore, a first drilled hole 33 and further drilled holes are arranged on the second base plate 48, via which the second adapter 2 is frictionally connected to the electronic device 42 by screw connections (not shown).

In order to enable a relative movement between the first adapter 1 and the second adapter 2, the first base plate 47 has an oval third cut-out 27 and further cut-outs in which screws (not shown) can carry out movements in the first drilled hole 33 and the further drilled holes relative to the first adapter 1.

Additionally, a first securing tab 29 and a second securing tab 30 are arranged in the first adapter 1 and a third securing tab 31 and a fourth securing tab 32 are arranged on the second adapter 2. In the assembled state shown in FIG. 1, the first securing tab 29 touches the third securing tab 31 and the second securing tab 30 touches the fourth securing tab 32.

With receptacles, which are configured as a second drilled hole 34 (not visible in FIG. 1) on the first securing tab 29 and a third drilled hole 35 on the third securing tab 31, the first securing tab 29 can be frictionally connected to the third securing tab 31 via a screw (not shown) as the fastener.

With receptacles, which are configured as a fourth drilled hole 36 (not visible in FIG. 1) on the second securing tab 30 and a fifth drilled hole 37 on the fourth securing tab 32, the second securing tab 30 can be frictionally connected to the fourth securing tab 32 via a screw (not shown) as the fastener.

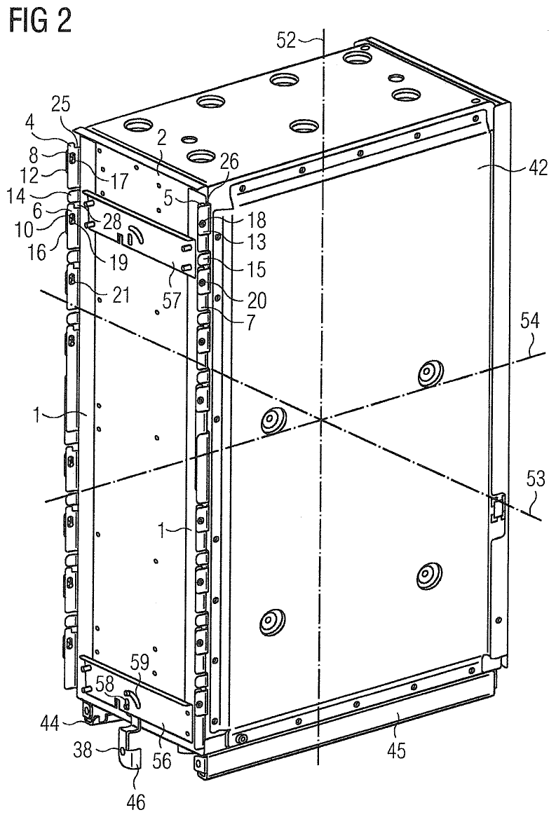

FIG. 2 shows a second exemplary embodiment of a fastening system in accordance with the invention with a first adapter 1 and a second adapter 2. A third adapter 3 shown in FIG. 3 is also part of the fastening system.

As distinct from the embodiment shown in FIG. 1, the first adapter 1 is configured in two parts and vertical edges of its first part and of its second part extend parallel to a vertical axis 52 and in the vicinity of rearward, vertical side edges of an electronic device 42. The first part and the second part are connected to one another via a first connecting plate 56 and a second connecting plate 57. Arranged between the first connecting plate 56 and the first adapter 1 and between the second connecting plate 57 and the first adapter 1, in each case, are four screw connections. The first connecting plate 56 is arranged in a lower region of the electronic device 42 and the second connecting plate 57 is arranged in an upper region.

The first adapter 1 comprises a first slotted tab 4, a second slotted tab 5, a third slotted tab 6, a fourth slotted tab 7 and further slotted tabs that have rectangular contours with rounded corners.

The second adapter 2 comprises a first guide tab 12 with a first guide pin 17, a second guide tab 13 with a second guide pin 18, a third guide tab 14 without a guide pin, a fourth guide tab 15 without a guide pin and further guide tabs with further guide pins and further guide tabs without guide pins.

The first guide tab 12, the second guide tab 13, the third guide tab 14, the fourth guide tab 15 and the further guide tabs have rectangular contours with rounded corners.

Connected to the first connecting plate 56 is a lever 46 that is arranged partially between the connecting plate 56 and the second adapter 2.

Arranged on the first connecting plate 56 are a first slotted guide 58 and a second slotted guide 59, via which the lever 46 can be transferred from a folded-in position into a folded-out position and via which the lever 46 can be transferred from a fold-out position to a fold-in position.

The lever 46 has a powder coating with a luminous green color.

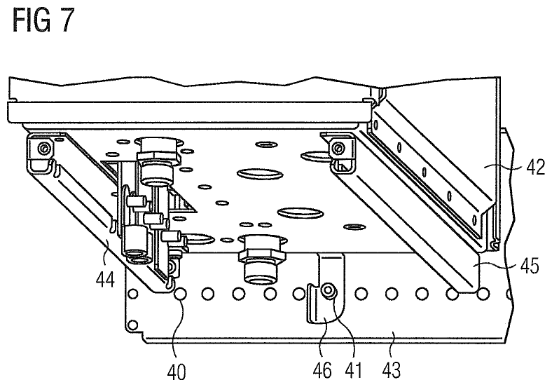

FIG. 2 shows a folded-out position of the lever 46, whereby it protrudes vertically downwardly. In a lower region of the lever 46, a sixth drilled hole 38 is provided via which, as shown in FIG. 7, the lever 46 can be fastened to a first wall 43 and the first adapter 1 can be locked.

Arranged on an underside of the electronic device 42 are a first profile 44 and a second profile 45 that are connected via screw connections (shown partially) to the electronic device 42. The first profile 44 can be introduced into a first rail (not shown) and the second profile 45 can be introduced into a second rail (not shown) that support the electronic device 42 and the fastening system. The first rail is arranged on a second wall (not shown) and the second rail is arranged on a third wall (not shown) of an equipment cabinet such that upon introduction of the electronic device 42 into the equipment cabinet, the first adapter 1 and the second adapter 2 are aligned vertically fittingly to the third adapter 3 (shown in FIG. 3) that is connected to a first wall 43 of the equipment cabinet. This fitting alignment has the effect that a first securing pin 22, a second securing pin 23 and further securing pins are arranged between the first slotted tab 4 and the first guide tab 12, the second slotted tab 5 and the second guide tab 13, the third slotted tab 6 and the third guide tab 14, the fourth slotted tab 7 and the fourth guide tab 15 and between further slotted tabs and further guide tabs and the electronic device 42 can be locked in the equipment cabinet.

In FIG. 2, an assembly state is shown in which the first adapter 1 has been displaced vertically upwardly relative to the second adapter 2 via the lever 46 in such a manner that the first securing pin 22 (not shown) can be arranged between the first slotted tab 4 and the first guide tab 12 in a first cut-out 25 formed on the first slotted tab 4, the second securing pin 23 (not shown) can be arranged between the second slotted tab 5 and the second guide tab 13 in a second cut-out 26 formed on the second slotted tab 5, and the further securing pins (not shown) can be arranged between further slotted tabs and further guide tabs in further cut-outs.In this state, the electronic device 42 is secured against unintended movements.

Otherwise, the principle illustrated in FIG. 2 and the selected reference characters correspond to the embodiment that is shown in FIG. 1.

FIG. 3 shows an oblique view of an exemplary embodiment of a third adapter 3 of a fastening system in accordance with the invention as shown, for example, in FIGS. 1 and 2, together with a portion of a first wall 43.

The third adapter 3 comprises a third base plate 49, a first side plate 50 and a second side plate 51 that are oriented at an angle of 90° to the third base plate 49. The third adapter 3 has a U-shaped cross-section. Formed on the third base plate 49 are a first keyhole cut-out 60, and further keyhole cutouts. The first wall 43 comprises a seventh drilled hole 39 that overlaps with the first keyhole cut-out 60 and further drilled holes which overlap with further keyhole cut-outs. With the first keyhole cut-out 60, the further keyhole cut-outs and the seventh drilled hole 39 along with further drilled holes, the third adapter 3 is connected to the first wall 43 with screw connections (not shown).

Arranged on the first side plate 50 are a first securing pin 22 and further securing pins, and arranged on the second side plate 51 are a second securing pin 23 and also further securing pins. The first securing pin 22, the second securing pin 23 and the further securing pins are arranged oriented parallel to a transverse axis 53.

Arranged in a region between the first side plate 50 and the second side plate 51 are conductors (not shown) of an electronic device 42 (also not shown in FIG. 3).

The first adapter 1 and the second adapter 2 shown in FIGS. 1 and 2 are introduced into the third adapter 3. For a locking of an electronic device 42, as described in relation to FIGS. 1 and 2, the first adapter 1 is displaced relative to the second adapter 2 such that at the end of this movement process, the first securing pin 22 is subsequently arranged in a first cut-out 25, the second securing pin 23 is subsequently arranged in a second cut-out 26 and the further securing pins are subsequently arranged in further cut-outs.

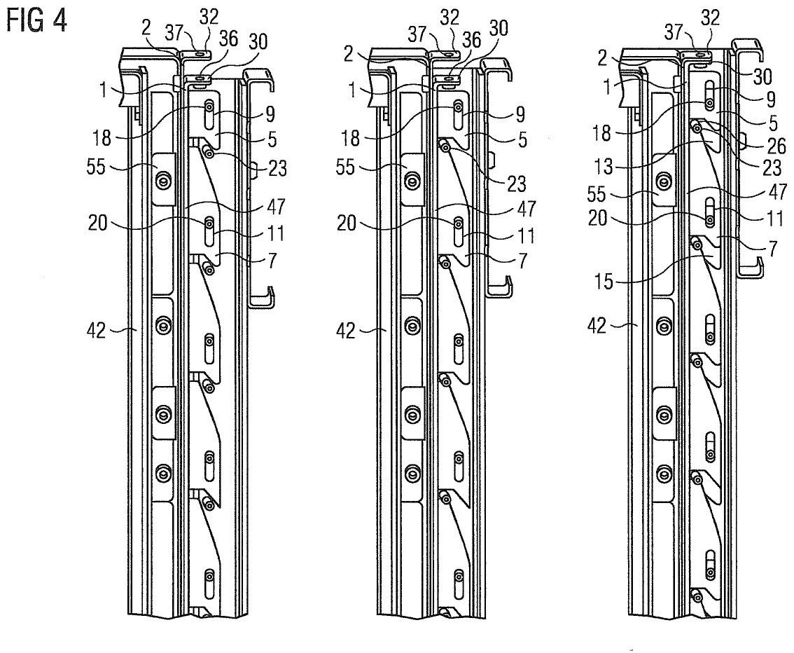

FIG. 4 shows side views of the first exemplary embodiment shown in FIG. 1 of a fastening system in accordance with the invention, where a respective state of an exemplary inventive locking process is shown in each of three drawings.

A first adapter 1 comprises a second slotted tab 5 with a second slot 9, a fourth slotted tab 7 with a fourth slot 11 and further slotted tabs with further slots. Furthermore, a second securing tab 30 with a fourth drilled hole 36 is arranged on the first adapter 1. The first adapter 1 adjoins a second adapter 2 that comprises a second guide tab 13 with a second guide pin 18, a fourth guide tab 15 with a fourth guide pin 20 and further guide tabs with further guide pins.

Furthermore, the second adapter 2 comprises a fourth securing tab 32 with a fifth drilled hole 37, which is arranged aligned with the second securing tab 30 and the fourth drilled hole 36.The second adapter 2 is connected to an electronic device 42 via the first connecting tab 55 and further connecting tabs.

The left-hand or bottom drawing shows a first state of the locking process in accordance with the invention, where a second securing pin 23 of a third adapter shown in FIG. 3 is arranged between the second slotted tab 5 and the fourth slotted tab 7 and further securing pins are arranged between further slotted tabs. The second securing tab 30 is not touching the fourth securing tab 32. The second guide pin 18 is arranged in an upper portion of the second slot 9, the fourth guide pin 20 is arranged in an upper portion of the fourth slot 11 and the further guide pins are arranged in upper portions of the further slots.

The middle drawing shows a state in which the second securing pin 23 is arranged between the second slotted tab 5, the fourth slotted tab 7 and a first base plate 47 of the first adapter 1 and the further securing pins are arranged between further slotted tabs and the first base plate 47 of the first adapter 1. Otherwise, this state matches that of the left-hand drawing.

The right-hand or top drawing shows a state in which, in comparison with the left-hand and middle drawings, the electronic device 42 has moved vertically downwardly with the second adapter 2 due to weight forces, and is held by the second securing pin 23 and the further securing pins.

The second guide pin 18 is arranged in a lower portion of the second slot 9, the fourth guide pin 20 is arranged in a lower portion of the fourth slot 11 and the further guide pins are arranged in lower portions of the further slots.

The second securing pin 23 is arranged between the second slotted tab 5, the fourth slotted tab 7, the second guide tab 13 and the first base plate 47 in a second cut-out 26, the further securing pins are arranged between further slotted tabs, further guide tabs and the first base plate 47 in further cut-outs.

The width of the second cut-out 26 corresponds to the diameter of the second securing pin 23, and the width of the further cut-outs corresponds to the diameters of the further securing pins.

The second securing tab 30 touches the fourth securing tab 32. With a fastener (not shown) (e.g., a screw), the second securing tab 30 can be connected to the fourth securing tab 32 and the fastening system can be locked.

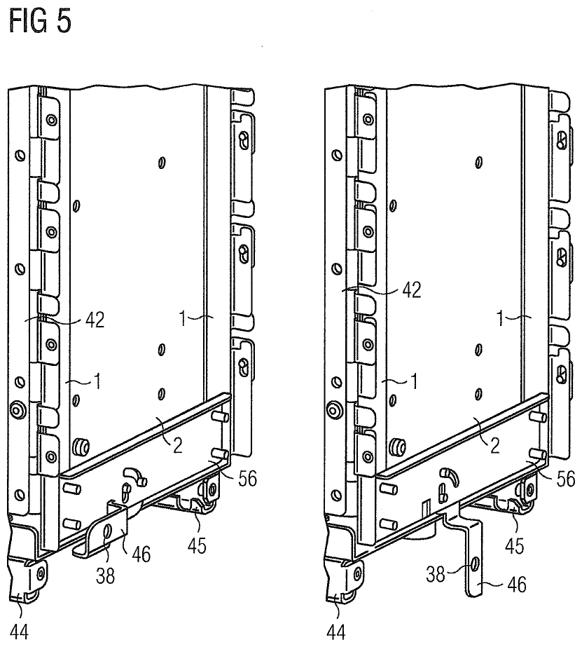

FIG. 5 shows oblique views of a second exemplary embodiment of a fastening system in accordance with the invention, where two states of an exemplary locking process in accordance with the invention are shown.

A first adapter 1 has a first connecting plate 56 with a lever 46. A second adapter 2 is firmly connected to an electronic device 42 and displaceably connected to the first adapter 1. Connected to the underside of the electronic device 42 are a first profile 44 and a second profile 45, via which the electronic device 42 can be introduced on rails (not shown) into an equipment cabinet (also not shown).

The left-hand drawing shows a first state in which the lever 46 is folded in and oriented horizontally.The right-hand drawing shows a second state in which the lever 46 is folded out and oriented projecting vertically downwardly. In this second state, the lever 46 can be connected via a sixth drilled hole 38 provided thereon and a fastener (e.g., a screw, not shown) to a first wall 43 shown, by way of example, in FIG. 7 and the fastening system can be locked.

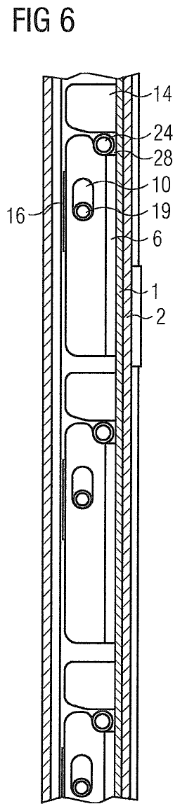

FIG. 6 shows a side view of a second exemplary embodiment of a fastening system in accordance with the invention, wherein one state of an exemplary locking process according to the invention is shown. A first adapter 1 comprises a third slotted tab 6 with a third slot 10, also further slotted tabs with further slots, a second adapter 2, a third guide tab 14, a fifth slotted tab 16 with a third guide pin 19 and further slotted tabs with and without further guide pins.

In the state shown, a third securing pin 24 is arranged between the third slotted tab 6 and the third guide tab 14 in a fourth cut-out 28 and further securing pins are arranged between further slotted tabs and further guide tabs in further cut-outs.

The width of the fourth cut-out 28 corresponds to the diameter of the third securing pin 24, the widths of the further cut-outs correspond to the diameters of the further securing pins.

An electronic device 42 connected to the second adapter 2 and illustrated, for example, in FIG. 2 is secured in this state against unintended movements.

FIG. 7 shows an oblique view of a second exemplary embodiment of a fastening system in accordance with the invention, where one state of an exemplary locking process in accordance with the invention is shown. Arranged on an underside of an electronic device 42 are a first profile 44 and a second profile 45.

An equipment cabinet (not shown) comprises a first rail connected to a second wall and a second rail connected to a third wall. The first profile 44 is arranged in the first rail, the second profile 45 is arranged in the second rail. The electronic device 42 is supported in the equipment cabinet via the first profile 44, the second profile 45, the first rail and the second rail.

A lever 46 connected to a first adapter 1 shown, by way of example, in FIG. 5 is folded out and projects vertically downwardly. A first wall 43 has an eighth drilled hole 40 and further drilled holes. With these further drilled holes, a sixth drilled hole 38 shown, by way of example, in FIG. 5 and arranged on the lever 46 as a receptacle for a fastener, and a securing screw 41 as the fastener, the lever 46 is connected to the first wall 43.

In this state, the position of the first adapter 1 as shown in FIG. 6 is fixed relative to a second adapter 2 and the fastening system is locked.

For the electronic device 42 shows in FIGS. 1, 2, 5 and 7, this is a favorable solution. In accordance with the invention, however, it is also conceivable for mechanical devices, automatic machines, etc. to be fastened with the fastening system shown.

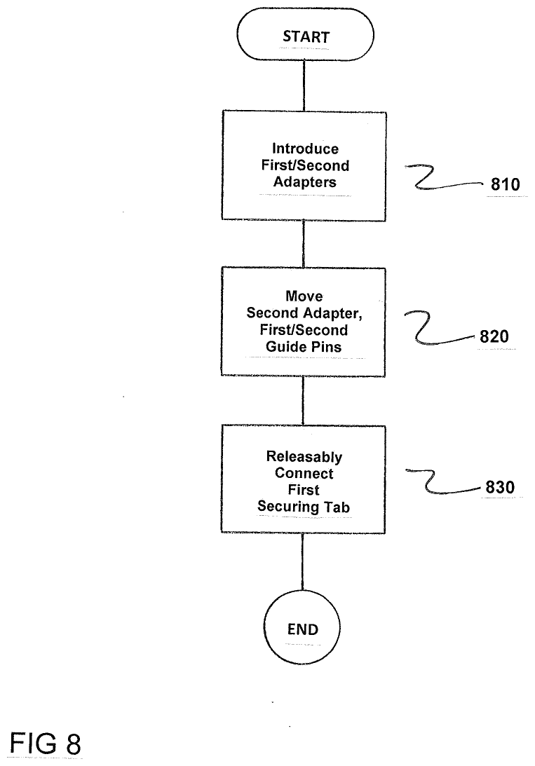

FIG. 8 is a flowchart of the method for locking of a fastening system in accordance with the invention. The method comprises introducing the first adapter 1 with the second adapter 2 into the third adapter 3 such that the at least one first slotted tab 4 of the fastening system subsequently hangs on the at least one first securing pin 22 and the second slotted tab 5 subsequently hangs on the second securing pin 23, as indicated in step 810.

Next, the second adapter 2, the first guide pin 17 in the first slot 8 and the second guide pin 18 in the second slot 9 are moved such that the at least one first securing pin 22 is subsequently arranged at least between the at least one first slotted tab 4 and the at least one first guide tab 12 in the first cut-out 25 and the second securing pin 23 is subsequently arranged at least between the second slotted tab 5 and the second guide tab 13 in the second cut-out 26, as indicated in step 820.

Next, the at least one first securing tab 29 is releasably connected via a fastener to the third securing tab 31, as indicated in step 830.

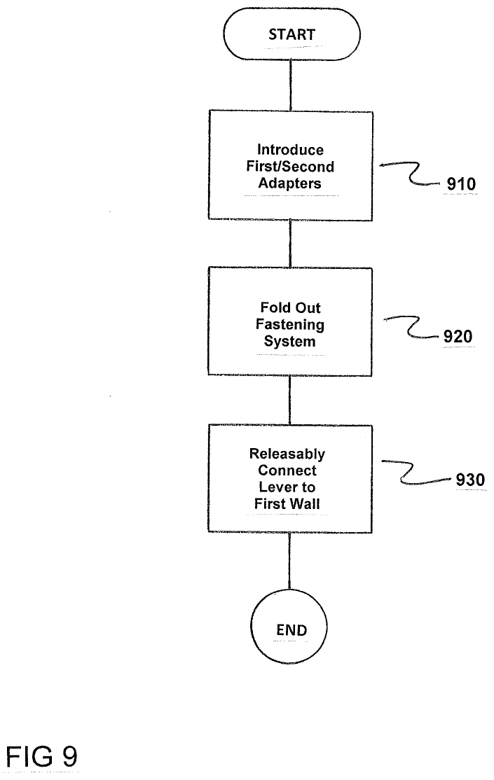

FIG. 9 is a flowchart of the method for locking of a fastening system in accordance with an alternative embodiment. The method comprises introducing the first adapter 1 with the second adapter 2 via the first profile 44 and the first rail and the second profile 45 and the second rail into the third adapter 3, as indicated in step 910.

Next, the lever 46 of the fastening system is folded out such that the first adapter 1 is displaced and the first guide pin 17 moves in the first slot 8 and the second guide pin 18 moves in the second slot 9 such that the at least one first securing pin 22 is subsequently arranged at least between the at least one first slotted tab 4 and the at least one first guide tab 12 in the first cut-out 25 and the second securing pin 23 is subsequently arranged at least between the second slotted tab 5 and the second guide tab 13 in the second cut-out 26, as indicated in step 920.

Next, the lever 46 of the fastening system and the first wall 43 are releasably connected to one another via the fastener, as indicated in step 930.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-15. (canceled)

16. A fastening system for, and connectable to, an electronic device, the fastening system comprising:
a first adapter comprising at least one first slotted tab with a first slot and a second slotted tab with a second slot, which are arranged at an angle;
a second adapter comprising at least one first guide tab with a first guide pin and a second guide tab with a second guide pin, which are arranged at a further angle;
a third adapter comprising at least one first securing pin and a second securing pin;
wherein, in an adjoined state of the first adapter with the second adapter in which the first adapter adjoins the second adapter, the second adapter is displaceably connected to the first adapter and the electronic device when connected to the second adapter is held by the at one least first securing pin and the second securing pin, the first guide pin is arranged in the first slot and the second guide pin is arranged in the second slot; and
wherein the at least one first securing pin, arranged between the at least one first slotted tab and the at least one first guide tab in a first cut-out, is lockable via the at least one first slotted tab and the at one least first guide tab, and the second securing pin, arranged between the second slotted tab and the second guide tab in a second cut-out, is lockable via the second slotted tab and the second guide tab.

17. The fastening system as claimed in claim 16, wherein the first cut-out is arranged on the at least one first guide tab and the second cut-out is arranged on the second guide tab; and wherein the first cut-out has a width of greater than or equal to a diameter of the at least one first securing pin and the second cut-out has a width of greater than or equal to a diameter of the second securing pin.

18. The fastening system as claimed in claim 16, wherein the first cut-out is arranged on the at least one first slotted tab and the second cut-out is arranged on the second slotted tab; and wherein the first cut-out has a width of greater than or equal to a diameter of the at least one first securing pin and the second cut-out has a width of greater than or equal to a diameter of the second securing pin.

19. The fastening system as claimed in claim 16, wherein the at least one first slotted tab, the second slotted tab, the at least one first guide tab and the second guide tab have a hook-shaped configured.

20. The fastening system as claimed in claim 16, wherein the first adapter has a third slotted tab and a fourth slotted tab.

21. The fastening system as claimed in claim 16, wherein the second adapter has a third guide tab and a fourth guide tab.

22. The fastening system as claimed in claim 16, wherein the first adapter comprises at least one first securing tab and the second adapter comprises at least one third securing tab; and wherein the at least one first securing tab and the at least one third securing tab comprise receptacles for a fastener.

23. The fastening system as claimed in claim 16, wherein the second adapter is releasably connectable.

24. The fastening system as claimed in claim 23, wherein the second adapter is releasably connectable to the electronic device.

25. The fastening system as claimed in claim 16, wherein the third adapter is releasably connected to a first wall.

26. The fastening system as claimed in claim 16, wherein conductors of the electronic device are arranged in a region between the first adapter and the third adapter.

27. The fastening system as claimed in claim 25, wherein the electronic device has a first profile and a second profile; wherein the first profile is arranged in a first rail which is releasably connected to a first wall and the second profile is arranged in a second rail which is releasably connected to a third wall.

28. The fastening system as claimed in claim 16, further comprising:
a lever connected to the first adapter, said lever having a receptacle for a fastener.

29. The fastening system as claimed in claim 28, wherein the lever is configured in a signal color.

30. A method for locking of a fastening system having a first adapter comprising at least one first slotted tab with a first slot and a second slotted tab with a second slot, which are arranged at an angle, a second adapter comprising at least one first guide tab with a first guide pin and a second guide tab with a second guide pin, which are arranged at a further angle; a third adapter comprising at least one first securing pin and a second securing pin, in an adjoined state of the first adapter with the second adapter in which the first adapter adjoins the second adapter, the second adapter being displaceably connected to the first adapter and the electronic device when connected to the second adapter being held by the at least one first securing pin and the second securing pin, the first guide pin being arranged in the first slot and the second guide pin being arranged in the second slot, and the at least one first securing pin, arranged between the at least one first slotted tab and the at least one first guide tab in a first cut-out, being lockable via the at least one first slotted tab and the at least one first guide tab, and the second securing pin, arranged between the second slotted tab and the second guide tab in a second cut-out, being lockable via the second slotted tab and the second guide tab, the method comprising:
introducing the first adapter with the second adapter into the third adapter such that the at least one first slotted tab of the fastening system subsequently hangs on the at least one first securing pin and the second slotted tab subsequently hangs on the second securing pin;
moving the second adapter, the first guide pin in the first slot and the second guide pin in the second slot such that the at least one first securing pin is subsequently arranged at least between the at least one first slotted tab and the at least one first guide tab in the first cut-out and the second securing pin is subsequently arranged at least between the second slotted tab and the second guide tab in the second cut-out; and
connecting the at least one first securing tab releasably via a fastener to the third securing tab.

31. A method for locking of a fastening system having a first adapter comprising at least one first slotted tab with a first slot and a second slotted tab with a second slot, which are arranged at an angle, a second adapter comprising at least one first guide tab with a first guide pin and a second guide tab with a second guide pin, which are arranged at a further angle; a third adapter comprising at least one first securing pin and a second securing pin, in an adjoined state of the first adapter with the second adapter in which the first adapter adjoins the second adapter, the second adapter being displaceably connected to the first adapter and the electronic device when connected to the second adapter being held by the at least one first securing pin and the second securing pin, the first guide pin being arranged in the first slot and the second guide pin being arranged in the second slot, and the at least one first securing pin, arranged between the at least one first slotted tab and the at least one first guide tab in a first cut-out, being lockable via the at least one first slotted tab and the at least one first guide tab, and the second securing pin, arranged between the second slotted tab and the second guide tab in a second cut-out, being lockable via the second slotted tab and the second guide tab, the method comprising:
introducing the first adapter with the second adapter via a first profile and a first rail and a second profile and a second rail into the third adapter;
folding out a lever of fastening system such that the first adapter is displaced and the first guide pin moves in the first slot and the second guide pin moves in the second slot such that the at least one first securing pin is subsequently arranged at least between the at least one first slotted tab and the at least one first guide tab in the first cut-out and the second securing pin is subsequently arranged at least between the second slotted tab and the second guide tab in the second cut-out; and
connecting the lever of the fastening system and the first wall releasably to one another via a fastener.
